(19) United States
(12) Patent Application Publication
(10) Pub. No.: US 2010/0085713 A1
(43) Pub. Date: Apr. 8, 2010

(54) LATERAL GRAPHENE HEAT SPREADERS FOR ELECTRONIC AND OPTOELECTRONIC DEVICES AND CIRCUITS

(76) Inventors: Alexander A. Balandin, Riverside, CA (US); Dmitri Kotchetkov, Riverside, CA (US); Suchismita Ghosh, Riverside, CA (US)

Correspondence Address: Klein, O'Neill & Singh, LLP - SRC, 43 Corporate Park, Suite 204, Irvine, CA, 92066, US

(21) Appl. No.: 12/418,297

(22) Filed: Apr. 3, 2009

Related U.S. Application Data
(60) Provisional application No. 61/102,773, filed on Oct. 3, 2008.

(51) Int. Cl. H05K 7/20; H01L 21/20; H01L 21/314; H01L 23/373

(52) U.S. Cl. 361/705; 438/478; 438/761; 257/E21.09; 257/E21.27; 257/E23.11

(57) ABSTRACT

A device and associated method of heat removal from electronic optoelectronic and photonic devices via incorporation of extremely high thermally conducting channels or embedded layers made of single-layer graphene (SLG), bi-layer graphene (BLG), or few-layer graphene (FLG).

This application claims the benefit and priority of U.S. Provisional Application Ser. No. 61/102,773, filed Oct. 3, 2008, which is incorporated herein by reference in its entirety for all purposes.

### BACKGROUND

1. Field of the Disclosure

This disclosure relates to the use of graphene for thermal management and high-flux cooling of electronic devices and circuits, such as field-effect transistors (FETs), integrated circuits (ICs), printed circuit boards (PCBs), three-dimensional (3D) ICs, and optoelectronic devices, such as light-emitting diodes (LEDs), and related electronic, optoelectronic, and photonic devices and circuits.

2. Description of Related Art

There is a trend in industry to reduce the size of semiconductor devices and integrated circuits. At the same time, the devices and circuits are designed to perform more functions. To satisfy the demands for reduced size and increased functionality, it becomes necessary to include a greater number of circuits in a given unit area. As a consequence of increased functionality and density in packaging, the devices and circuits use more power. This power is typically dissipated as heat generated by the devices. The increased heat generation, coupled with the need to reduce size, leads to an increase in the amount of heat generated per unit area. The increase in the amount of heat generated in a given unit area leads to a demand to increase the rate at which heat is transferred from the devices and circuits to heat sinks or to ambient environment in order to prevent them from becoming damaged due to exposure to excessive heat.

Heat removal from the downscaled electronic devices, highly integrated circuits, high-power electronic devices, light emitting photonic devices, or high-speed electronic or optoelectronic devices has become a major problem for further development of these technologies. The conventional methods of heat removal mostly rely on the packaging and system-level cooling.

### SUMMARY

This present disclosure relates to a device and associated methods of forming the device that provides improved heat removal capabilities from electronic, optoelectronic and photonic devices and ICs via incorporation of high thermally conducting channels made of graphene.

This disclosure offers several embodiments using lateral heat spreaders based on graphene. Graphene, as discovered by the inventors, is characterized by extremely high thermal conductivity, which allows it to be used for heat removal. The embodiments use the flat geometry of graphene, which allows it to be readily incorporated into the device structure. The embodiments allow for better thermal management of the electronic and optoelectronic devices and circuits and reduced power consumption.

In one aspect, a method is provided for forming an electronic device comprising forming a graphene layer on a substrate; forming a layer of an insulating material on top of the graphene layer; forming an active layer of a semiconductor material on top of the insulating layer; and forming device components in the active layer.

In another aspect, a method is provided for forming an electronic device comprising providing a substrate of a first material including a plurality of grooves, each groove including a heat sink of a second material; forming a graphene layer on the substrate, at least a portion of the graphene layer contacting at least a portion of the heat sinks; forming a layer of an insulating material on top of the graphene layer; forming an active layer of a semiconductor material on top of the insulating layer; and forming device components in the active layer.

In yet another aspect, a method is provided for forming an electronic device comprising forming a first layer on a substrate; implanting a graphitized layer into the first layer; transforming the graphitized layer into an electrically insulating amorphous carbon material; forming an active layer of a semiconductor material on top of the first layer; and forming device components in the active layer.

In yet another aspect, an electronic device is provided including an insulative substrate having a first surface; a graphene layer on the first surface of the substrate; a layer of an insulating material on the graphene layer; and an active layer of a semiconductor material on the insulating layer, wherein the active layer includes semiconductive device components.

Additional advantages, objects, and features of the disclosed embodiments are set forth in part in the detailed description that follows. It is to be understood that both the foregoing general description and the following detailed description are merely exemplary embodiments, and are intended to provide an overview or framework for understanding the nature and character of the disclosed subject matter.

### BRIEF DESCRIPTION OF THE DRAWINGS

Embodiments of the present disclosure now will be discussed in detail with an emphasis on highlighting the advantageous features. These embodiments depict the novel and non-obvious system and methods shown in the accompanying drawings, which are for illustrative purposes only. These drawings include the following figures, in which like numerals indicate like parts:

FIG. 1 is a simplified schematic representation showing a configuration of a heat-generating semiconductor device which has a standard silicon substrate and does not have a special heat spreader layer;

FIG. 2 is a simplified schematic representation showing a configuration of a heat-generating semiconductor device which is made with silicon-on-insulator (SOI) technology and does not have a special heat spreader layer;

FIG. 3 is a simplified schematic representation showing a configuration of a heat-generating semiconductor device made with a standard silicon substrate or SOI technology with a diamond layer used as a heat spreader;

FIG. 4 is a simplified schematic representation showing a configuration of a flip-chip integrated circuit in a high-performance package with an external heat sink;

FIG. 5 is a simplified schematic representation showing a cross-section of a Printed Circuit Board;

FIG. 6A is a representation of an image of graphene flakes, and FIG. 6B is a schematic representation of an experimental setup, used in the finding of the extremely high thermal conductivity of graphene;

FIG. 7 is a block diagram illustrating a benefit of using graphene in heat removal;

FIG. 8 is a simplified schematic representation showing a heat-generating semiconductor device configured according to a first embodiment of the present disclosure;

FIG. 9 is a simplified schematic representation showing a heat-generating semiconductor device configured according to a second embodiment of the present disclosure, where graphene is directly placed on the substrate or grown on it by CVD or other technique;

FIG. 10 is a simplified schematic representation showing a heat-generating semiconductor device configured according to a third embodiment of the present disclosure;

FIG. 11 is a simplified schematic representation showing a modified form of the embodiment of FIG. 10 where graphene is directly placed on the substrate or grown on it by CVD or other technique;

FIG. 12 is a simplified schematic representation of a bonding and flipping process that may be used to fabricate semiconductor devices or ICs with the graphene heat spreader configured according to embodiments of the present disclosure;

FIG. 13 is a simplified schematic representation showing a semiconductor device with a composite graphene—diamond lateral heat spreader configured according to a fourth embodiment of the present disclosure;

FIG. 14 is a simplified schematic representation showing a semiconductor device configured according to a fifth embodiment of the present disclosure, where graphene is placed or grown on a diamond substrate instead of conventional silicon or other semiconductor substrate;

FIG. 15 is a simplified schematic representation showing a flip-chip integrated circuit in a high performance package configured according to a sixth embodiment of the present disclosure;

FIG. 16 is a simplified schematic representation showing a cross-section of a Printed Circuit Board configured according to a seventh embodiment of the present disclosure;

FIG. 17 is a simplified schematic representation showing a device configured according to another embodiment of the present disclosure, where a thick silicon wafer is substituted with thinned silicon substrate;

FIG. 18 is a simplified schematic representation showing a device configured according to another embodiment of the present disclosure, where a graphene layer is attached to a thinned silicon substrate and then placed on synthetic diamond; and

FIG. 19 is a simplified schematic representation showing a device configured according to another embodiment of the present disclosure, illustrating removal of heat from the three-dimensional (3D) electronic circuits.

### DETAILED DESCRIPTION

The present disclosure considers two major silicon-based technologies in semiconductor device manufacturing. The first uses standard silicon substrates, while the second uses layered silicon-insulator-silicon substrates. The latter is usually referred as silicon-on-insulator (SOI) technology. The SOI technology helps reduce parasitic device capacitance and thereby improves the performance of a device.

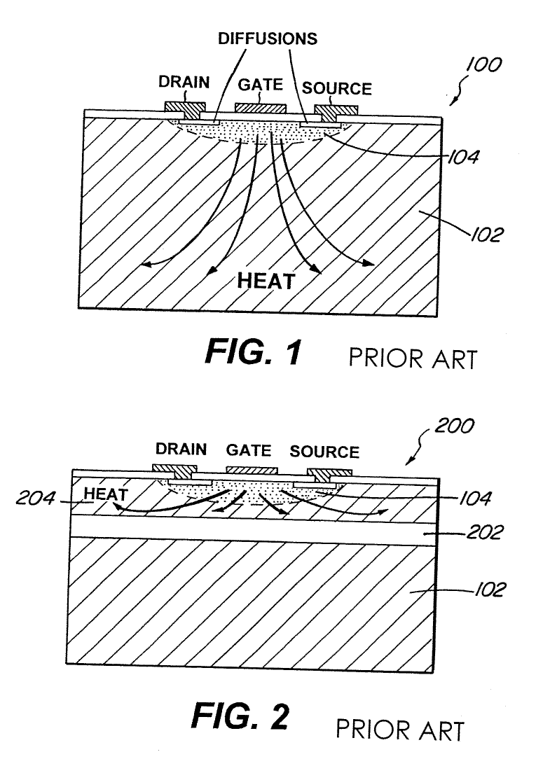

FIG. 1 is a schematic representation showing a configuration of a typical prior art heat-generating semiconductor device 100, which has a standard silicon substrate 102 and does not have a special heat spreader layer. In the standard semiconductor technology, the device components are placed on the silicon substrate 102, which has the room temperature thermal conductivity of ˜147 Wm⁻¹K⁻¹. Heat is usually generated in a localized volume and distributed non-uniformly through the wafer. For example, in metal-oxide-semiconductor field-effect transistors (MOSFETs), the heat is generated in the source-drain channel 104. The heat then propagates with a near-spherical heat front through the substrate material. As a result, the heat is distributed unequally through the substrate. Thus, the amount of heat per unit volume generally varies in different parts of the substrate, having maximal values under the source-drain channel or in other heat generating areas such as the interconnect wiring. Non-uniformity in heat distribution leads to the appearance of hot spots and device performance degradation.

The thermal conductivity of the substrate, together with the area of the heat front, defines how much heat can be removed from the device components within a given time period. The thermal conductivity of the substrate and the area of the heat front are factors that limit the ability to remove the heat and avoid damage to the device. Due to the near-spherical heat front, the volume directly under the source-drain channel typically has the highest temperatures in the substrate.

FIG. 2 is a schematic representation showing a configuration of a conventional prior art heat-generating semiconductor device 200 which is made with silicon-on-insulator (SOI) technology and does not have a special heat spreader layer. In SOI technology, an electrical insulator 202 is placed on the silicon substrate 102 and a second layer of silicon 204 is placed on top of the insulator 202. In one embodiment, silicon dioxide (SiO₂) is a preferred insulator for improved performance and diminished short channel effects, while sapphire is commonly used for radiation-sensitive applications.

SiO₂-based wafers may be produced by any of the following processes:
1) Separation by implantation of oxygen (SIMOX), which uses an oxygen ion beam implantation process followed by high temperature annealing to create a buried SiO₂ layer;
2) Wafer bonding, in which the insulating layer is formed by directly bonding oxidized silicon with a second substrate. The majority of the second substrate is subsequently removed, the remnants forming the topmost Si layer; or
3) Seed methods, where the topmost Si layer is grown directly on the insulator.

This method requires a template for homoepitaxy, which may be achieved by chemical treatment of the insulator, appropriate orientation of the crystalline insulator, or vias through the insulator from the underlying substrate.

Heat removal from the source-drain channel is more problematic in SOI devices. As in a standard silicon substrate, heat propagates nearly spherically from the source-drain channel, but only an insignificant fraction of the generated heat is able to dissipate into the SiO₂ layer 202. Most of the heat remains in the top most Si layer 204 as the heat waves are reflected from the Si-SiO₂ boundary. This results in an increasing heat flux in the top Si layer 204 and in an increasing risk of overheating and damaging the device.

One of the most promising new means for improving heat removal from electronic and optoelectronic devices is to incorporate heat conductors into the device structure, thereby addressing the thermal management problem at the materials and device level. In this approach, materials with high thermal conductivities are placed close to the active region of the circuit. Such materials serve as heat spreaders.

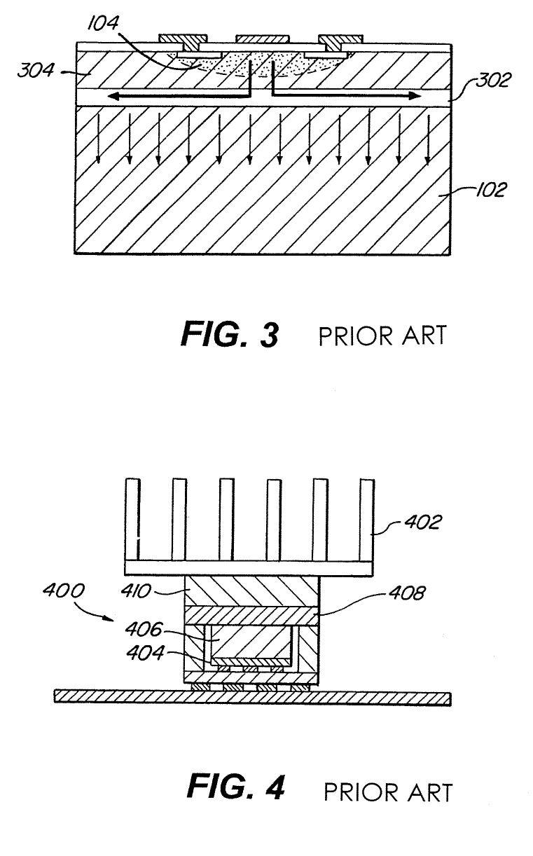

One of the existing heat removal technologies applied in MOSFETs is a modification of the SOI technology where the insulator layer 202 of SiO₂ (FIG. 2) is replaced by the polycrystalline diamond layer 302. In this example, synthetic diamond has been used as a heat spreader material. FIG. 3 is a schematic representation showing a configuration of a heat-generating semiconductor device, for example, a MOSFET, made with SOI technology using an insulator layer 302 made of a diamond material for use as the heat spreader.

Another heat removal technology is illustrated in FIG. 4, which shows a configuration for a flip-chip processor 400 attached to an external heat sink 402, which is typically air-cooled. The temperature of a chip 404 depends upon the thermal performance of both the package and the heat sink. The main heat flow path from the chip to air is Chip 404=> TIM1 406=> Lid 408=> TIM2 410=> Heat sink 402=> Air, where TIM is an acronym for Thermal Interface Material. The package contribution to this path is determined by the thermal conductivity of TIM1 406 and of the lid 408 (heat spreader).

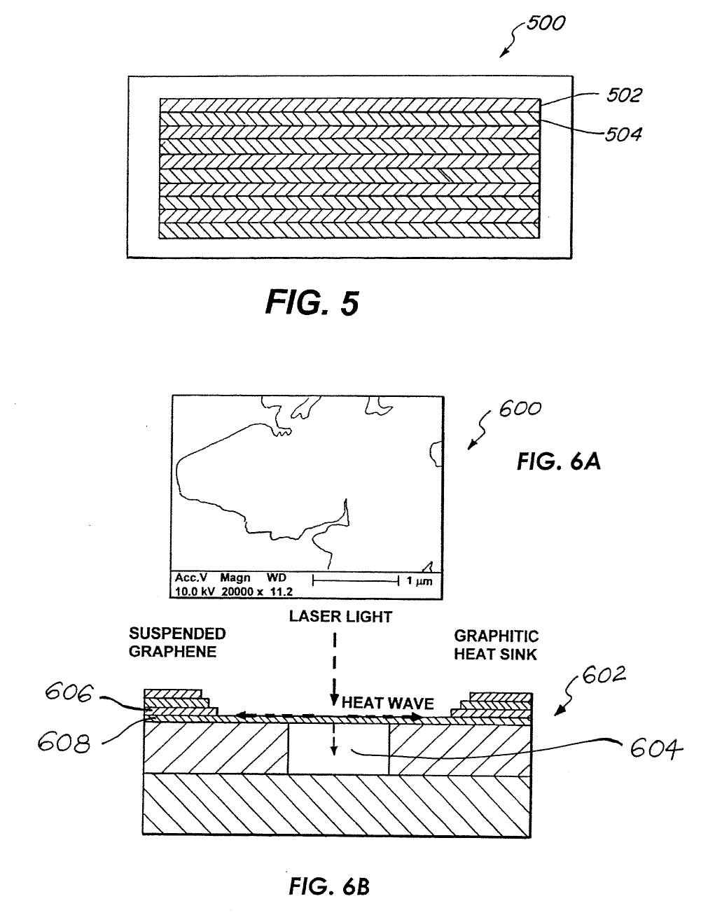

There is also an increasing demand to improve heat removal performance of Printed Circuit Boards (PCBs). FIG. 5 is an illustration of a PCB 500, which is typically a laminated structure of a conductive metal 502, such as a copper foil, and an insulative composite 504, such the glass-reinforced polymer known as FR-4. In this example, the thermal conductivity of copper is ˜400 Wm⁻¹K⁻¹ while the thermal conductivity of FR-4 is ˜0.25 Wm^{31 1}K⁻¹. Due to low FR-4 thermal conductivity, heat propagates in-plane through the copper layers. Thus, the value of the copper thermal conductivity is a dominating limiting factor in heat removal in most PCBs.

Advances in the thermal performance of processor packages are ultimately determined by innovations in materials for these components. It has been found by the inventors of the current disclosure that graphene has a thermal conductivity that is greater than that of diamond and carbon nanotubes, and thus is an excellent material for thermal management. As shown in the embodiments that follow, graphene may be used as a heat spreader material and incorporated into device and chip designs in ways that are not possible with other materials. The proposed embodiments of graphene heat spreaders include graphene layers in MOSFETs, integrated circuit packages, PCBs and as a filler material in TIMs as proposed for example in the following embodiments.

FIG. 6A is a representation of an image 600 of graphene and FIG. 6B is a schematic representation of an experimental setup used in finding the extremely high thermal conductivity of graphene. The relatively high thermal conductivity of graphene was determined by the inventors using a new measurement technique based on micro-Raman spectroscopy. Graphene is a one-atom-thick planar sheet of sp²-bonded carbon atoms that are packed in a hexagonal crystal lattice. Graphene has a number of unique properties, which include superior electron mobility. It has been found by the inventors that graphene manifests high thermal conductivity relative to some other materials. The room temperature thermal conductivity of single layer graphene has been measured to be in the range of 3100-5300 Wm⁻¹K⁻¹.

Referring to FIGS. 6A and 6B, in the measurements that proved the high thermal conductivity of graphene, the layers of graphene were obtained by the mechanical exfoliation (repeated pealing) of small mesas of bulk highly oriented pyrolitic and Kish graphite. For the measurement of the thermal conductivity, such layers were suspended over a trench 604 made by reactive ion etching in an Si/SiO₂ substrate. The depth of the trench 604 was ˜300 nm with a width of 1-5 μm. The large graphitic pieces 606 attached to single graphene layer 608 acted as heat sinks. In some embodiments, the graphene layers can be produced by mechanical exfoliation from Kish, HOPG or other bulk graphite; by chemical vapor deposition (CVD) growth; by chemical exfoliation and reduction of graphene layers from bulk graphite; temperature processing of SiC or other carbon growth technique.

It has been shown by the inventors that the “G peak” in the Raman spectra of graphene shows strong temperature dependence. This allows monitoring of the temperature change produced by a variation of the laser excitation power focused on the graphene layer 608. To generate a heat spot in graphene, the laser light was focused in the middle of the suspended graphene sheet 608. Since air and silicon dioxide have relatively low values of thermal conductivity (˜0.025 Wm⁻¹K⁻¹ and ˜1 Wm⁻¹K⁻¹, respectively) the thermal coupling of graphene with silicon dioxide was minimal. As a result, the heat was forced to propagate in-plane through the graphene layer 608, with the thickness of ˜0.35 nm, toward the heat sinks 606. The extremely small cross-sectional area of the heat conduction channels made possible the detection of the temperature variations in the layers. It was assumed that the heat flow forms two planar wave-fronts in opposite directions toward the trench edges. Such an assumption was made because the size of the laser hot spot was comparable to the width of the graphene layer.

The thermal conductivity K is extracted using the following expression:

K=χ_{G}(L/2hW)(δω/δP)⁻¹, (3)

where χ_{G}=0.016 cm⁻¹/K is the coefficient which defines a s temperature, L is the distance from the middle of the suspended graphene layer (geometrical center of the laser spot) to the heat sink, h and W are the thickness and the width of the graphene layer, respectively, δω is the shift in the G peak position in the Raman spectrum, and δP is the change in the heating power.

With changing the heating power of the spectrometer and measuring the changes in the G peak position, the thermal conductivity was calculated for several graphene samples. The measured value was within the range of 3100-5300 Wm⁻¹K⁻¹.

The present disclosure provides a description of a method of heat removal and thermal management of electronic, optoelectronic, photonic devices and electronic circuits through incorporation of heat spreading layers made of single layer graphene (SLG), bi-layer graphene (BLG), and few-layer graphene (FLG). The disclosure encompasses several specific device and circuit structures as particular embodiments of the heat removal method with graphene.

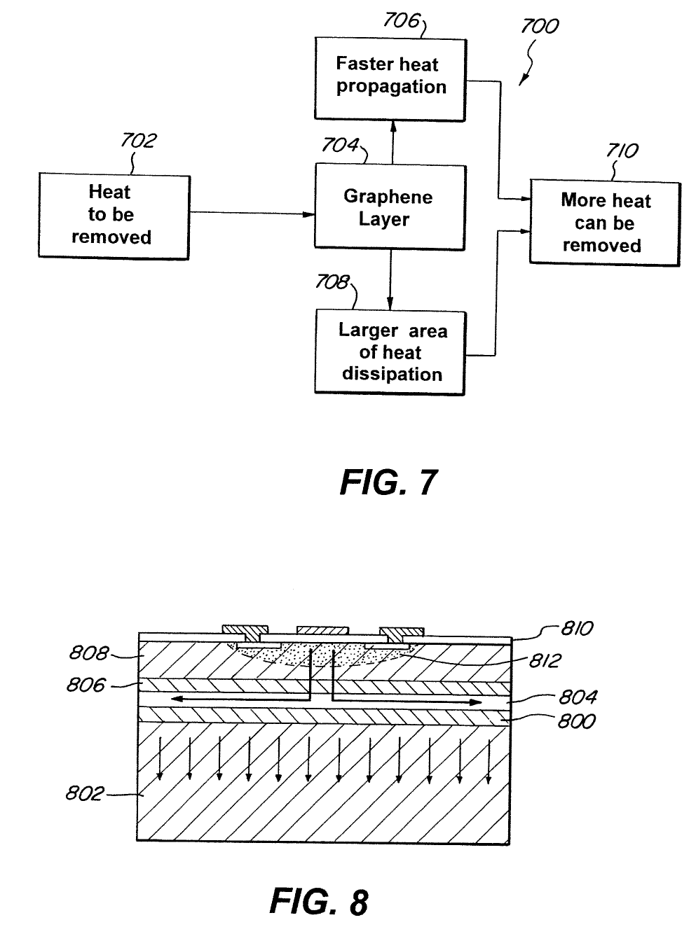

FIG. 7 is a block diagram 700 illustrating a benefit of using graphene in heat removal in accordance with some embodiments. As mentioned, graphene has a high thermal conductivity and represents a one-atom-planar sheet of carbon. The thickness of one plane of graphene is approximately 0.35 nm. In all embodiments, a SLG or FLG may be used depending on the device size, materials selection, graphene growth process and the like. The number of graphene layers (e.g. total thickness of the overall graphene layer) is selected to achieve the optimum heat removal. A graphene layer (704) placed within a semiconductor device under a heat source (702) causes the heat to quickly propagate (706) laterally through the graphene layer (704). Thereafter, the heat dissipates from the graphene layer into the substrate of the semiconductor device. The graphene layer increases the area (708) through which the heat dissipates into the substrate; thus it reduces the heat to be removed per unit area per unit time (heat flux) (710). Moreover, the heat flux becomes more uniform. Also, a part of or a whole graphene layer may be placed on a bulk material which has high thermal conductivity, thus increasing the allowable rate at which the heat can be taken away from the heat source. As a result, the semiconductor device is able to use higher power per unit area.

Although, graphene may be employed as a heat removal component of a MOSFET, unlike diamond, graphene is an electrical conductor, and thus should be isolated from the active layer of the transistor. This can be done by placing an insulator (SiO₂, diamond, amorphous carbon, diamond-like carbon, and the like) between the graphene and the material of the active layer (Si, GaN, InN, and the like).

FIG. 8 illustrates a first embodiment. A layer of buffer material 800 is placed on a device substrate 802. In one embodiment, the buffer material layer 800 is provided to facilitate graphene growth, for example, by epitaxial growth, CVD, and the like, or placement of the mechanically exfoliated graphene on top of the buffer material layer 800.

Alternatively, when graphene is produced by heat treatment of SiC, the substrate 802 and the buffer material layer 800 may be replaced by a SiC wafer. In one embodiment, the buffer material 800 includes a lattice structure similar to that of graphene (namely, hexagonal), thus allowing growth or incorporation of graphene on the buffer material layer 800. Buffer materials with high thermal conductivity are preferable. Suitable materials for the buffer material layer 800 are described below, and, as discussed below, the specific buffer material 800 may depend on the material of the substrate 802. The thickness of the buffer material layer 800 may vary between, for example, 1 to 5 μm, to have minimum impact on heat conduction from a graphene layer to the substrate 802.

In one embodiment, one or more planar layers of graphene 804 may be placed on the buffer material layer 800. An electrically insulating layer 806, having a thickness of, for example, between about 0.1 to 5 μm, is placed on top of the graphene layer 804. The insulating layer 806 separates the graphene layer 804, which is an electric conductor, from the active semiconductor layer 808 of the device. In one embodiment, the thickness of the electrically insulating layer 806 is selected to have minimum impact on heat conduction from the active device layer 808 to the graphene layer 804. The insulating layer 806 may include a synthetic polycrystalline diamond or other electrically insulating heat conducting materials. Graphene may be naturally grown from the synthetic diamond through the known process of diamond graphitization or by the high-pressure high-temperature (HPHT) growth technique or other techniques. A thin layer of a semiconductor material is deposited or placed on top of the insulating layer 806 to provide the active layer 808, implementing the components of the device (gate, drain, source, and the like) by appropriate doping, as is well-known in the art, and forming a drain-source channel 812. Finally, an insulative gate isolation layer 810 (typically SiO₂) is applied over the active layer 808, as is well-known in the art.

Due to the extraordinary high value of the graphene thermal conductivity (3100-5300 Wm⁻¹K⁻¹) and graphene's planar structure, the heat quickly propagates laterally through the graphene plane(s) 804 and later dissipates into the substrate 802 through the buffer material layer 800. The heat from the drain-source channel 812 is quickly removed, and the area of the heat dissipation is substantially increased, thereby reducing the heat flux and making it more uniform. The graphene incorporation allows hot spots to be removed and spreads the heat more uniformly.

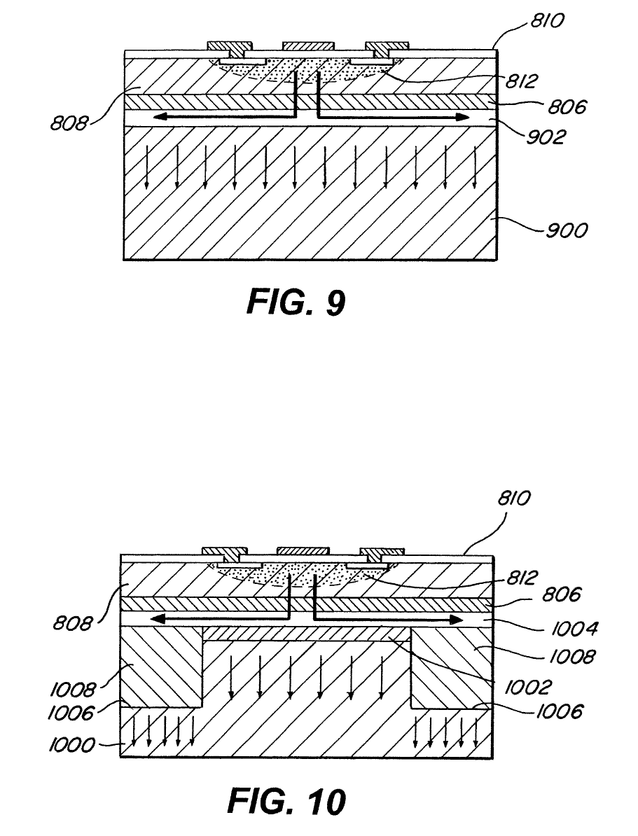

FIG. 9 illustrates a second embodiment. This embodiment is similar to other embodiments, except there is no buffer layer between a substrate 900 and a graphene layer 902. This embodiment may be employed when the substrate material and the graphene have matching lattice structures, or when graphene can be successfully grown directly on the substrate 900, thus making placement of the buffer layer redundant. The insulating layer 806 may include a synthetic polycrystalline diamond or other electrically insulating heat conducting materials. The incorporation of graphene with the room-temperature thermal conductivity of up to ˜5000 Wm⁻¹K⁻¹ significantly improves the lateral heat spreading.

FIG. 10 illustrates a third embodiment. This embodiment is similar to the above-described embodiments, with a buffer 1002 disposed between at least a portion of substrate 1000 and at least a portion of one graphene layer 1004. In this embodiment, however, the substrate 1000 may be provided with a plurality of grooves 1006, into each of which a piece of thermally conductive material 1008, such as bulk graphite is disposed. The graphene layer(s) 1004 are formed on the substrate in a manner to contact the thermally conductive material 1008, which serve as heat sinks. The thermal conductivity of the material 1008 may have a very broad range of values. For example, a maximum achievable value is about 2000 Wm⁻¹K⁻¹ which is a single crystal plane thermal conductivity. This embodiment allows somewhat faster heat removal from the heat source where the material of the substrate has a thermal conductivity that is lower than that of thermally conductive material 1008, for example, Si (˜147 Wm⁻¹K⁻¹).

In the embodiment in which the thermally conductive material 1008 is bulk graphite, due to the excellent attachment of the graphene layers 1004 to the thermally conductive material 1008 (graphene is a single atomic layer of graphite), the problem of the thermal conductive resistance between the graphene lateral heat spreader 1004 and the heat sinks 1008 is avoided. That is because graphene forms a natural attachment to bulk graphite placed in the grooves 1006.

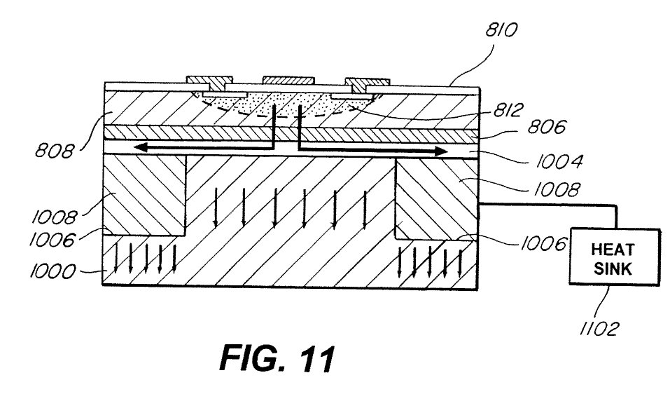

As shown in FIG. 11, at least one of the graphite heat sinks 1008 may be thermally coupled to an external heat sink 1102 in or on the IC or device package. FIG. 11 illustrates that the third embodiment may omit the buffer 1002 shown in FIG. 10.

Similar embodiments are possible with optoelectronic device structures, such as LEDs and semiconductor lasers, in which a graphene heat spreader may be incorporated within the optoelectronic device structure. The present disclosure and specific embodiments are to be implemented with many different materials and using different fabrication technologies. The present disclosure does not limit the choices for materials used for the substrate, the buffer layer, the insulating layer, and the active layer. Similarly, the disclosure does not limit the choices for processes used to fabricate a MOSFET with graphene as a component for heat removal. Some exemplary materials with relatively high thermal conductivities that may be used for the substrate are shown in Table 1.

TABLE 1
Thermal conductivities of the materials used for substrates.

| Material for the substrate | Thermal conductivity (Wm⁻¹K⁻¹) |
|---|---|
| Diamond | 1000-2000 |
| Sapphire | 35 |
| GaN | 130 |
| AlN | 200 |
| SiC (pure) | 490 |
| SiC (polycrystalline) | 300 |
| Si | 147 |
| BN | 250 |

If, for example, Si is used for the substrate, and one has to fabricate the MOSFET according to the second embodiment, then SiC may be employed as a material for the buffer layer. SiC is deposited on the Si substrate using chemical vapor deposition. Methyltrichlorosilane (CH₃SiCl₃) is traditionally used as a precursor for SiC growth on Si.

In this example, graphene layers are grown epitaxially on SiC by thermal decomposition of Si. The top surface of the SiC layer may be prepared by oxidation or H₂ etching. Then the SiC layer is heated to ˜1000° C. by electron bombardment under ultrahigh vacuum (1.3×10⁻⁸ Pa) conditions to remove the oxide. Then the layer is heated to temperatures of about 1250-1450° C. for 1-20 min. Under these conditions, graphene layers are formed, with the thickness determined predominantly by the temperature.

The material of the insulating layer placed on top of the graphene heat spreader may be any insulating material, but materials with hexagonal lattice structures are preferred. The deposition of the insulating layer on top of graphene is less complex if the lattice constant of the insulating material has a value close to that of graphene. Similar choices of such hexagonal crystals may be made for MOSFET substrates (the above-described first embodiment) or the buffer layers. For example, hexagonal BN can be grown on Si substrates using supersonic molecular jet epitaxy and microwave plasma assisted CVD using borane-triethylamine complex ((CH₃CH₂)₂BH₂:BH₃) and tris(sec-butyl)borane ([CH₃CH₂CH(CH₃)]₃B) as precursors.

A semiconductor material (Si, GaN, and the like) is deposited on top of the insulating layer to create the active layer of the device.

Instead of material growth, wafer bonding techniques may be employed to fabricate the MOSFET with the graphene heat spreader in accordance with some embodiments.

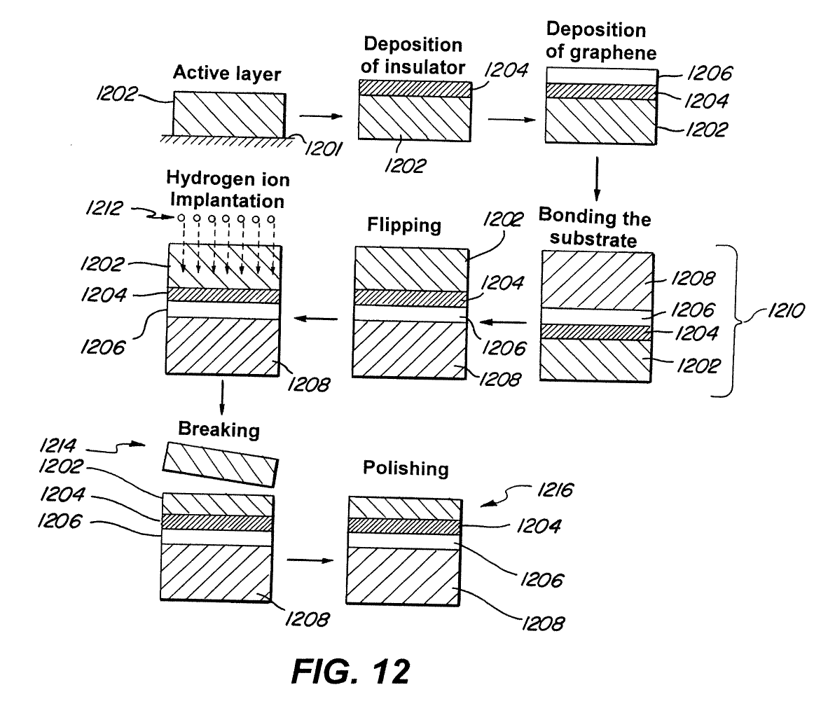

As illustrated in FIG. 12, one of the options to fabricate the MOSFET according to several of the above described embodiments, for example, the second embodiment of FIG. 9, is to use a bonding and flipping technology. In this embodiment, an insulator or insulating layer 1204 is deposited on a substrate 1202 made from the material used for the device's active layer. The active layer substrate 1202 is positioned on, for example, a preparation surface 1201. In this embodiment, the created insulating layer 1204 is thin. A graphene layer 1206 is grown on top of the insulating layer 1204. Next, a wafer 1208 made from the material usually used for the MOSFET substrates is bonded to the graphene layer 1206 from the top. The resulting structure 1210 is flipped upside-down with the wafer 1208 becoming the device's substrate, which can be placed on the same or a different preparation surface 1201 for further processing. The thickness of the top active layer 1202 is reduced by hydrogen ion implantation 1212 and breaking 1214 with subsequent surface polishing 1216. For the embodiments of FIGS. 10 and 11, making grooves for the heat sinks 1008 in the substrate wafer and placing these pieces in the grooves are done before bonding the substrate wafer.

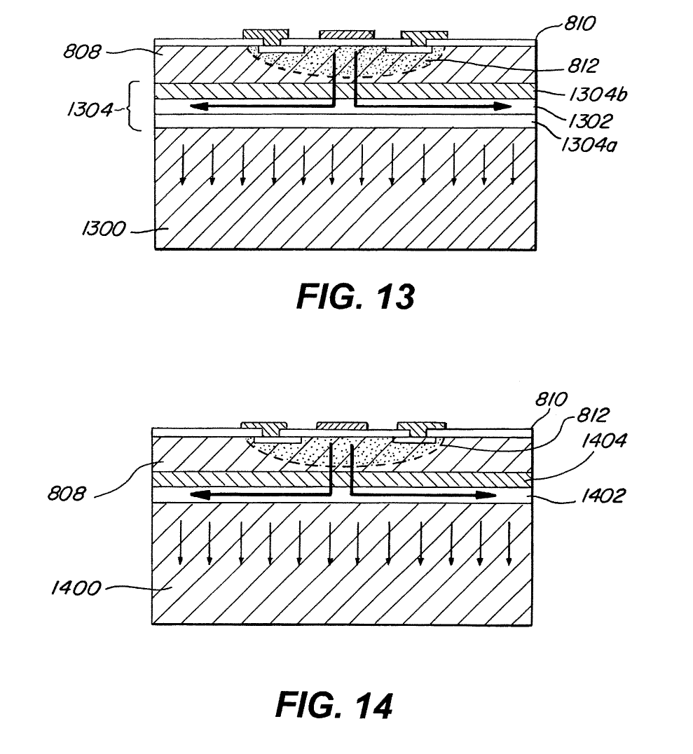

FIG. 13 illustrates a fourth embodiment. This embodiment repeats the first embodiment except both the buffer layer 1304a and the insulating layer 1304b are made from the polycrystalline (or single crystal or micro-crystalline) diamond layer 1304. In one embodiment, the buffer and insulating layers 1304a and 1304b are made from a single diamond layer 1304. A layer of graphene 1302 is embedded into the diamond layer 1304 using a graphitization technique to separate the diamond layer 1304 into the buffer and insulating layers 1304a and 1304b. In the graphitization technique, C⁺ ions with the energies of the order of ˜100 keV are implanted in the diamond layer 1304. As a result, a buried graphitized layer 1302 is created with the buffer layer 1304a and the insulating layer 1304b created on either side. After annealing in a vacuum at 1500 ° C., diamond in the graphitized layer 1302 transforms from a material with sp³ bonded carbon into a material with sp³ bonded carbon, which corresponds to a graphene lattice.

FIG. 14 illustrates a fifth embodiment. In this embodiment, synthetic diamond is used as the material for a substrate layer 1400. An internal layer of graphene 1402 is created in the diamond substrate 1400 through graphitization, thereby forming a diamond overlayer 1404 above the graphene layer 1402. A thin active layer of a semiconductor material 808 is placed on top of the diamond overlayer 1404. The active layer 808 is used to implement the components of the device (gate, drain, source, etc.). This MOSFET configuration makes the use of the buffer and insulating layers redundant.

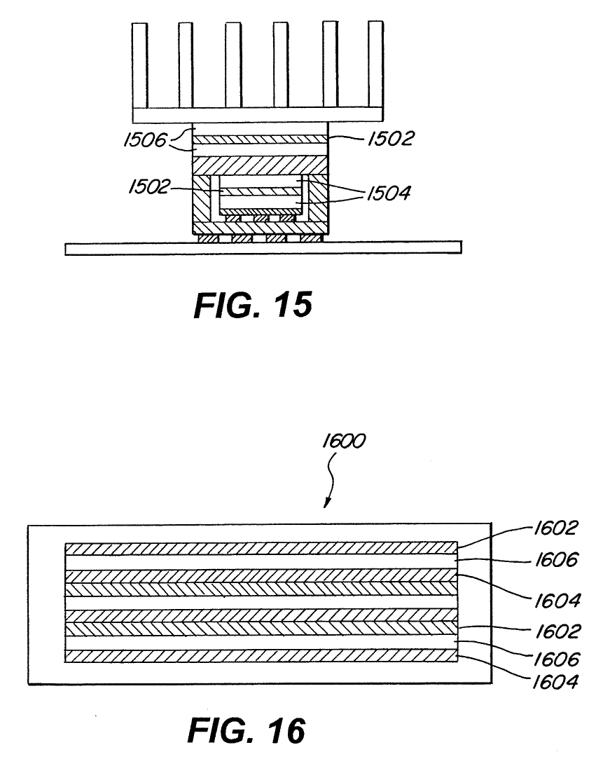

FIG. 15 illustrates a sixth embodiment. Graphene layer(s) 1502 are embedded in the thermal interface material (TIM). In this case graphene flakes may be used as filler material for the TIMs. Even a small volume fraction of graphene is sufficient to increase the thermal conductivity of the TIMs. Due to its high thermal conductivity and its geometric shape, graphene is better filler material than, for example, carbon nanotubes. In this example, the two TIM layers 1504 and 1506 are of a composite material and are used to improve the heat transport through the sectional interfaces. The TIM improves the heat propagation by filling the air gaps and performing the function of the heat spreader In one embodiment, thermal grease may be used as the TIM basis (matrix materials) combined with graphene flakes, to reduce the cost. In another embodiment, metal particles (for example, silver) are suspended together with graphene flakes in silicon grease (“paste”) which serves as the medium. As an alternative to metallic particles, ceramic and other non-metallic materials may be used, such as beryllium oxide, aluminum nitride, diamond, or others. Table 2 presents a list of some exemplary materials that may be used together with graphene flakes in the grease. Presence of graphene in the grease results in an increase of its heat removal efficiency.

TABLE 2
Thermal conductivities of the materials used
as fillings in thermal greases.

| Material for the substrate | Thermal conductivity (Wm⁻¹K⁻¹) |
|---|---|
| Diamond | 1000-2000 |
| Sapphire | 35 |
| BeO | 220 |
| AlN | 200 |
| ZnO | 20 |
| BN | 250 |

FIG. 16 illustrates a seventh embodiment. Graphene is used as a heat spreader in a printed circuit board (PCB) 1600, which is a laminated structure consisting of conductive metal layers 102 (e.g., copper foil) and insulative layers 1604 formed from a composite (e.g. fiber-reinforced polymer such as FR-4). In one embodiment, graphene flakes are placed in the structure in such a way that they form a graphene layer 1606 between each metal layer 1602 and each insulative layer 1604. The number of the metal and insulative layers may be chosen according to specific PCB design demands. One or several layers of graphene may be placed within the structure. If the metal layers are copper foil, the high thermal conductivity of copper (400 Wm⁻¹K⁻¹) provides very good thermal coupling between the conductive layers and the graphene. Thus, the combination of graphene and copper increases the tolerable flux of heat that may be taken away from electronic devices placed on the PCB. Alternatively, in one embodiment, graphene layers (SLG or FLG) may be embedded inside the insulating polymer layers. Graphene can be fabricated inside polymer matrix material and, in turn, used in the PCB manufacturing.

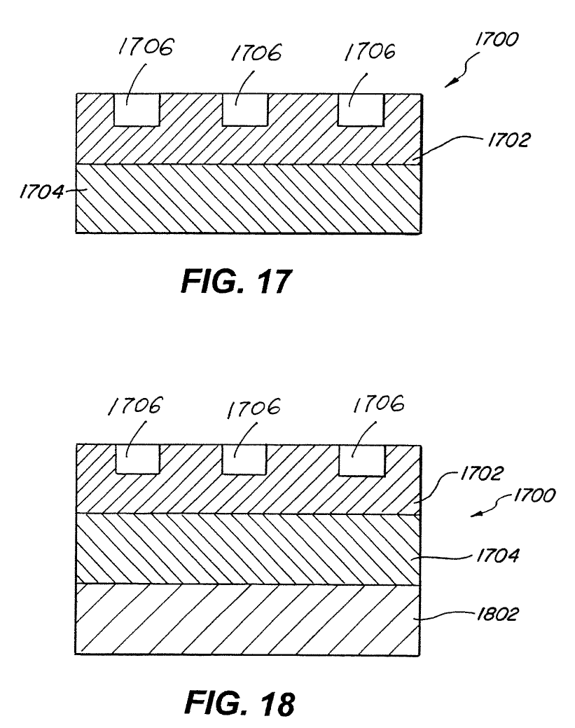

FIG. 17 is a simplified schematic representation showing a device configured according to another embodiment of the present disclosure, where a thick silicon wafer is substituted with thinned silicon substrate. The embodiment illustrates a device structure 1700 using a thinned silicon substrate 1702 to substitute for a thicker layer. The thinned silicon substrate 1702 is attached to a graphene layer (SLG or FLG) or graphite layer 1704 thus forming a composite substrate assembly with improved thermal capability. The devices, interconnects and other heat generating components 1706 are formed on top of the thinned silicon substrate 1702 in a conventional manner.

FIG. 18 is a simplified schematic representation showing a device configured according to another embodiment of the present disclosure, where a graphene layer is attached to a thinned silicon substrate and then placed on synthetic diamond. This embodiment illustrates the device structure 1700 using the thinned silicon substrate 1702 and the graphene layer (SLG or FLG) 1704 attached to the thinned silicon substrate 1702. The assembly is then placed on a synthetic diamond 1802 thus forming a composite wafer with improved heat removal properties. The devices, interconnects and other heat generating components 1706 are formed on top of the thinned silicon substrate in a conventional manner.

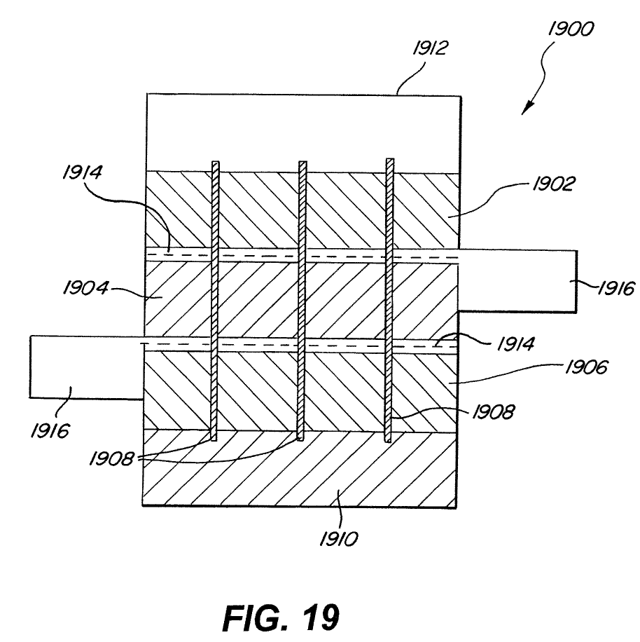

FIG. 19 shows a structure 1900 and method for heat removal from 3D electronic circuits in accordance with an embodiment. The structure 1900 may be formed by stacking chips, dies or wafers (hereinafter “tiers”). In this embodiment, the structure 1900 includes three tiers 1902, 1904 and 1906 formed between a heat sink 1912 and a wafer 1910. The structure 1900 also includes vertical thermal vias 1908, which are formed through each tier 1902, 1904 and 1906 to contact the bottom wafer 1910 and the heat sink 1912. In this embodiment, graphene layers 1914 are formed between the tiers 1902, 1904 and 1906. The addition of the lateral graphene layers 1914 in 3D electronic ICs allows the heat to escape more rapidly from the inside regions of 3D chips that otherwise have only the vertical vias 1908 to remove the heat. The graphene layers 1908 may be coupled to “lateral” heat sinks 1916, which may be implemented from bulk graphite to facilitate the connection to the graphene layers 1908.

The present disclosure shows clear advantages over existing practices. There are no known applications of graphene as a heat spreader material in semiconductor devices and circuits, integrated circuit packaging, or PCBs. Most manufactured semiconductor devices and integrated circuits do not include thermal management components embedded in the substrates. Traditional means of heat removal (micro liquid cooling, air blowing, and external heat sinks) still remain ineffective for hot-spot removal in the region near drain-source current or new interconnect wiring. That region absorbs most of the generated heat and remains to be a part of the device or circuit most likely to be damaged from excessive heat. Embedding a layer of the material with high thermal conductivity in the substrate provides an increase in tolerable heat flux. Moreover, the heat propagates laterally within the graphene plane, which results in an increase in the area of heat dissipation, reduction of the heat flux, and more uniform heat absorption by the substrate. Graphene has more than twice the thermal conductivity of diamond, allowing an increase in the rate of heat removal. Graphene temperature processing requirements are lower than those for diamond. Employing graphene as a heat spreader material in semiconductor devices, chip packaging, and PCBs makes an increase of tolerable power possible.

The embodiments described may be advantageously employed in manufacturing field-effect transistors, integrated circuits, printed circuit boards, optoelectronic devices such as light-emitting diodes, and related electronic, optoelectronic, and photonic devices and circuits. Use of graphene as a thermal management component makes heat removal more efficient, and thus the devices and circuits can use more power and with extended life.

The above description presents the best mode contemplated for carrying out the present embodiments, in such full, clear, concise, and exact terms as to enable any person skilled in the art to which they pertain to practice the embodiments. The embodiments are, however, susceptible to modifications and alternate constructions from those discussed above that are equivalent. Consequently, the disclosure is not limited to the particular embodiments disclosed. On the contrary, the disclosure covers all modifications and alternate constructions coming within the spirit and scope of the embodiments as generally expressed by the following claims which particularly point out and distinctly claim the subject matter of the invention.

What is claimed is:

1. A method for forming an electronic device comprising:
forming a graphene layer on a substrate;
forming a layer of an insulating material on top of the graphene layer;
forming an active layer of a semiconductor material on top of the insulating layer; and
forming device components in the active layer.

2. The method of claim 1, wherein forming the graphene layer on the substrate comprises growing the graphene from a synthetic diamond through a process of diamond graphitization.

3. The method of claim 1, wherein the substrate comprises a material that has a lattice structure matching the lattice structure of the graphene.

4. The method of claim 1, further comprising forming a layer of buffer material between the graphene layer and the substrate that facilitates graphene growth.

5. The method of claim 1, wherein forming the graphene layer on the substrate comprises forming layers of graphene by mechanical or chemical exfoliation of graphene from bulk graphite and transferring the exfoliated graphene on the substrate.

6. The method of claim 1, wherein forming the graphene layer on the substrate comprises forming layers of graphene by directly growing the graphene by chemical vapor deposition (CVD) on the substrate.

7. The method of claim 1, wherein the layer of insulating material comprises a synthetic polycrystalline diamond, diamond-like carbon or similar carbon material.

8. The method of claim 1, wherein the substrate comprises synthetic diamond, and wherein forming the graphene layer on the substrate and forming the layer of the insulating material on top of the graphene layer comprises:
creating an internal layer of graphene in the diamond substrate to form the graphene layer through graphitization, thereby creating a diamond overlayer to form the insulating layer above the graphene layer.

9. A method for forming an electronic device comprising:
providing a substrate of a first material including a plurality of grooves, each groove including a heat sink of a second material;
forming a graphene layer on the substrate, at least a portion of the graphene layer contacting at least a portion of the heat sinks;
forming a layer of an insulating material on top of the graphene layer;
forming an active layer of a semiconductor material on top of the insulating layer; and
forming device components in the active layer.

10. The method of claim 9, wherein the first material comprises Si, GaAs, InAs, GaN, SiC, and the second material is bulk graphite or metal.

11. The method of claim 9, further comprising forming a buffer disposed between at least a portion of the substrate and the graphene layer.

12. The method of claim 9, further comprising coupling at least one of the heat sinks to an external heat sink.

13. A method for manufacturing an electronic device with the embedded graphene heat spreader comprising:
providing a substrate including material suitable for an active layer and positioning the active layer substrate on a preparation surface;
depositing an insulator on the active layer substrate;
growing graphene on the insulator;
bonding a wafer to the graphene; and
flipping the resulting structure upside down causing the wafer to be positioned on a preparation surface while further processing.

14. A method for forming an electronic or optoelectronic device comprising:
forming a first layer on a substrate;
implanting a graphitized layer into the first layer;
transforming the graphitized layer into an insulating carbon material;
forming an active layer of a semiconductor material on top of the first layer; and
forming device components in the active layer.

15. The method of claim 14, wherein the first layer comprises a polycrystalline (single crystal) synthetic diamond layer.

16. The method of claim 14, wherein implanting the graphitized layer into the first layer comprises causing the first layer to be separated into a buffer layer on a first side of the graphitized layer and an insulating layer on a second side of the graphitized layer.

17. An electronic or optoelectronic device with the embedded graphene heat spreader comprising:
an insulative substrate having a first surface;
a graphene layer on the first surface of the substrate;
a layer of an insulating material on the graphene layer; and
an active layer of a semiconductor material on the insulating layer, wherein the active layer includes semiconductive device components.

18. The device of claim 17, wherein the graphene layer is grown from a synthetic diamond through a process of diamond graphitization, CVD growth or transferred to the substrate after being chemically or mechanically exfoliated from bulk graphite.

19. The device of claim 17, wherein the insulative substrate comprises a material that has a lattice structure matching the lattice structure of the graphene layer.

20. The device of claim 17, further comprising a layer of buffer material between the graphene layer and the first surface of the substrate that facilitates graphene growth.

21. The device of claim 17, wherein the layer of insulating material comprises a synthetic polycrystalline diamond.

22. A device with an embedded heat spreader comprising:
a structure formed by:
forming a graphene layer on a substrate;
forming a layer of an insulating material on top of the graphene layer;
forming an active layer of a semiconductor material on top of the insulating layer; and
forming device components in the active layer.

23. A method for forming an electronic device comprising:
forming a composite structure including a thin silicon substrate and a graphene layer on a substrate;
placing the composite structure on a synthetic diamond; and
forming heat generating components on the thin silicon substrate.

24. A method for forming a 3D electronic device comprising:
stacking tiers of substrate materials between a heat sink and a wafer;
forming graphene layers between each of the stacked tiers; and
forming vertical heat vias through the tiers connected to the wafer at a first end and the heat sink at a second end.

25. The method of claim 24, further comprising coupling the graphene layers to external heat sinks.

26. The method of claim 24, wherein the tiers of substrate materials comprise wafers, chips and dies.

27. A device with an embedded heat spreader comprising:
a structure formed by:
stacking tiers of substrate materials between a heat sink and a wafer;
forming graphene layers between each of the stacked tiers; and
forming vertical heat vias through the tiers connected to the wafer at a first end and the heat sink at a second end.

28. The device of claim 27, wherein the graphene layers are coupled to external heat sinks.

26. The device of claim 27, wherein the tiers of substrate materials comprise wafers, chips and dies.
